(19) United States
(12) Patent Application Publication
(10) Pub. No.: US 2014/0151570 A1
(43) Pub. Date: Jun. 5, 2014

(54) CHARGED PARTICLE BEAM LENS AND EXPOSURE APPARATUS USING THE SAME

(71) Applicants: Takahisa Kato, Brookline, MA (US); Yutaka Setomoto, Tokyo (JP)

(72) Inventors: Takahisa Kato, Brookline, MA (US); Yutaka Setomoto, Tokyo (JP)

(73) Assignee: CANON KABUSHIKI KAISHA, Tokyo (JP)

(21) Appl. No.: 14/004,845

(22) PCT Filed: Mar. 14, 2012
(86) PCT No.: PCT/JP2012/001773

§ 371 Date: Feb. 24, 2014

(30) Foreign Application Priority Data
Mar. 15, 2011 (JP) 2011-056813

(51) Int. Cl. H01J 37/12

(52) U.S. Cl. CPC H01J 37/12
USPC 250/396 R

(57) ABSTRACT

An electrostatic charged particle beam lens includes an electrode including a flat plate having a first surface having a normal line extending in a direction of an optical axis and a second surface opposite to the first surface, the electrode having a through-hole extending from the first surface to the second surface. When an opening cross section is defined as a cross section of the through-hole taken along a plane perpendicular to the normal line and a representative diameter is defined as a diameter of a circle obtained by performing regression analysis of the opening cross section, a representative diameter of the opening cross section in a first region that is on the first surface side and a representative diameter of the opening cross section in a second region that is on the second surface side are smaller than a representative diameter of the opening cross section in a third region that is a region in the electrode disposed between the first surface and the second surface.

### TECHNICAL FIELD

The present invention relates to the technical field of electron optical systems that are used in apparatuses using a charged particle beam such as an electron beam. In particular, the present invention relates to an electron optical system that is used in an exposure apparatus. In the present invention, the term “light” refers not only to visible light but also to electromagnetic radiation such as an electron beam or the like.

### BACKGROUND ART

In the production of semiconductor devices, electron beam exposure technology is a promising lithography technology that enables exposure of a fine pattern with a width of 0.1 micrometers or smaller. In electron beam exposure apparatuses, an electron optical element is used to control optical characteristics of an electron beam. Electron lenses are classified into an electromagnetic type and an electrostatic type. The structure of an electrostatic electron lens is simpler than that of an electromagnetic electron lens because an electrostatic electron lens does not have a coil core. Therefore, the electrostatic type is advantageous in reduction in size. Regarding the electron beam exposure technology, multi-beam systems, which form a pattern by simultaneously using a plurality of electron beams instead of using a mask, have been proposed. A multi-beam system includes an electron lens array in which electron lenses are arranged one dimensionally or two dimensionally. In the electron beam lithography technology, the limit of microfabrication is not determined by the diffraction limit of an electron beam but by optical aberrations of an electron optical element. Therefore, it is important to realize an electron optical element having small aberrations.

For example, PTL 1 describes a charged particle beam lens array including a plurality of charged particle beam lenses that are arranged two-dimensionally and that are divided into at least two groups having different refractive powers when the same voltage is applied to all lenses.

### CITATION LIST

### Patent Literature

PTL 1: Japanese Patent Laid-Open No. 2007-123599

### SUMMARY OF INVENTION

### Technical Problem

An electrostatic charged particle beam lens has a structure simpler than that of an electromagnetic lens. However, optical aberrations of an electrostatic charged particle beam lens are highly sensitive to a fabrication error of an opening of the lens. In particular, when the opening is circular, astigmatism of the lens is sensitive to the symmetry of the shape of the opening, such as the circularity (deviation of a circular shape from a perfect circle) of the opening. An electron beam that is converged under the influence of an asymmetric opening has astigmatism or another high order aberration.

In particular, this problem is important when a plurality of electron beams having different astigmatisms is used, because such astigmatisms cannot be corrected by using an ordinary stigmator.

Moreover, when the rigidity of an electrode is low, the electrode may become deformed by an electrostatic attraction force generated due to a voltage for controlling electron optical characteristics. If the electrode becomes deformed, an error occurs in the focal length of the lens.

In particular, this is an important problem in the case of an electron lens array that controls a plurality of electron beams, because an electrode has a large area so that openings can be arranged like an array and thereby the rigidity of the electrode is likely to be reduced.

According to an aspect of the present invention, an electrostatic charged particle beam lens includes an electrode including a flat plate having a first surface having a normal line extending in a direction of an optical axis and a second surface opposite to the first surface, the electrode having a through-hole extending from the first surface to the second surface. When an opening cross section is defined as a cross section of the through-hole taken along a plane perpendicular to the normal line and a representative diameter is defined as a diameter of a circle obtained by performing regression analysis of the opening cross section, a representative diameter of the opening cross section in a first region that is on the first surface side and a representative diameter of the opening cross section in a second region that is on the second surface side are each smaller than a representative diameter of the opening cross section in a third region that is a region in the electrode disposed between the first surface and the second surface.

### Advantageous Effects of Invention

With the charged particle beam lens according to the present invention, the aberration of the electrode can be reduced without improving the fabrication precision. Moreover, the first and second regions may have small thicknesses. Therefore, openings can be easily formed in the first and second regions having a high contribution to the aberration of the lens aberration and an opening having good circularity can be formed at low cost. Moreover, the third region may have large thickness, so that the rigidity of the entirety of the electrode can be increased. Because the contribution of the third region to the aberration is low, increase in the aberration can be restrained without improving the precision of fabrication.

### BRIEF DESCRIPTION OF DRAWINGS

FIG. 1A is a sectional view of a charged particle beam lens according to a first embodiment of the present invention.

FIG. 1B is a top view of the charged particle beam lens according to the first embodiment of the present invention.

FIG. 2A is an enlarged sectional view of a portion surrounded by broken line M in FIG. 1A.

FIG. 2B is a sectional view of an opening when the diameters D1 and D2 are the same.

FIG. 3A is an enlarged sectional view of a portion surrounded by broken line Y in FIG. 2A.

FIG. 3B is a graph illustrating change in a coefficient Kf of expression (1).

FIG. 3C is a graph illustrating change in the differential coefficient of the co-efficient Kf.

FIG. 4 is a graph illustrating the thicknesses and the contributions to the aberration of the first and second regions according to the present invention.

FIG. 5 is a table illustrating an actual exemplary design according to the first embodiment.

FIG. 6 is a conceptual diagram illustrating mechanisms with which a charged particle beam lens converges an electron beam.

FIG. 7 is a diagram illustrating the distribution of potential in the vicinity of an opening of the charged particle beam lens.

FIG. 8 is a conceptual diagram of a charged particle beam lens according to an existing technology.

FIG. 9 is a conceptual diagram of an opening according to an existing technology.

FIG. 10 is a graph illustrating a design example of the third region according to the first embodiment.

FIG. 11A is a conceptual diagram illustrating the definition of the circularity of an opening cross section.

FIG. 11B is a conceptual diagram illustrating the definition of the circularity of an opening cross section.

FIG. 11C is a conceptual diagram illustrating the definition of the circularity of an opening cross section.

FIG. 11D is a conceptual diagram illustrating the definition of the circularity of an opening cross section.

FIG. 11E is a conceptual diagram illustrating the definition of the circularity of an opening cross section.

FIG. 11F is a conceptual diagram illustrating the definition of the circularity of an opening cross section.

FIG. 12 is a sectional view of a charged particle beam lens array according to a second embodiment of the present invention.

FIG. 13A is a conceptual diagram illustrating the definition of the representative diameter and the representative radius of an opening cross section.

FIG. 13B is a conceptual diagram illustrating the definition of the representative diameter and the representative radius of an opening cross section.

FIG. 13C is a conceptual diagram illustrating the definition of the representative diameter and the representative radius of an opening cross section.

FIG. 14 is a conceptual diagram illustrating the definition of representative diameters along the thickness direction.

FIG. 15 is a sectional view of an opening according to the first embodiment of the present invention.

FIG. 16 is a graph illustrating the contribution of the aberration of a third region according to the first embodiment of the present invention.

FIG. 17A is a graph illustrating the distribution of the circularity of the third region.

FIG. 17B is a graph illustrating the contribution of the aberration of the third region.

FIG. 18 is a graph illustrating the diameters and the distribution of aberration of the third region.

FIG. 19 is a conceptual diagram illustrating a lithography system using a charged particle beam according to the third embodiment of the present invention.

### DESCRIPTION OF EMBODIMENTS

In the present invention, the terms “first surface” and “second surface” respectively refer to one of the surfaces (front surface) and the other surface (back surface) of an electrode of a charged particle beam lens according the present invention. The terms “first region”, “second region”, and “third region” refer to three segments of the electrode having predetermined thicknesses in the thickness direction.

In the present invention, the phrase “through-holes extending from the X-th surface to the Y-th surface (where X and Y are integers in the range from 1 to 6)” refers to a through-hole through which the X-th surface and the Y-th surface are connected to each other. It does not matter in which direction the through-hole is formed. That is, the through-hole may be formed from the X-th surface, from the Y-th surface, or from both of these surfaces.

In a charged particle beam lens according to the present invention, an opening is segmented into first, second, and third regions, so that the representative diameter of the third region is larger than those of the first and second regions. Thus, the contribution of the opening cross sections in the second and third regions can be reduced. Therefore, the aberration of an electrode can be reduced without increasing the fabrication precision. Moreover, the thicknesses of the first and second regions can be reduced. Therefore, openings in the first and second regions, which have high contributions to the aberration of the lens, can be formed easily, and thereby an opening having a good circularity can be formed at low cost. Furthermore, the rigidity of the entirety of the electrode can be increased by increasing the thickness of the third region. Because the third region, which has a large thickness, has a low contribution to the aberration, increase of the aberration can be restrained. That is, increase in the aberration can be restrained without increasing the fabrication precision of the third region.

In the charged particle beam lens according to the present invention, the shape errors of the openings in the first region and the second region (corresponding to the circularity according to the present invention, which will be described below) may be smaller than the shape error of the opening in the third region. With such a structure, the opening cross sections in the first and second regions, which have high contributions to the aberration of the entirety of the lens, are formed with high precision, the tolerance of error in forming the opening in the third region can be increased. Moreover, by increasing the thickness of the third region, the thickness and the rigidity of the entirety of the lens can be increased.

In the charged particle beam lens according to the present invention, the ratio D1/D2 of the diameters D1 and D2 may be equal to or larger than 0.4 and smaller than 1.0. With such a structure, both deformation of the openings in the first and second regions and variation in the deformation due to a fabrication error can be reduced. Therefore, variation in the circularity of the openings in the first and second regions due to the deformation and variation in the effective diameter D1 can be reduced.

In the charged particle beam lens according to the present invention, the thickness of the first and second regions may be smaller than that of the third region. With such a structure, the precision of fabrication of the openings in the first and second regions can be made higher than that in the third region. Because a thick (deep) through-hole is to be formed in the third region, which has a large tolerance of error, the difficulty and the cost of forming a through-hole in a substrate can be reduced.

The charged particle beam lens according to the present invention may be configured such that the sum of the aberrations of the openings in the first and second regions determines 80% of the aberration of the entirety of the electrodes. In this case, the circularity of the opening in the third region is allowed to be twice the circularity of the first and second regions or larger. By making the circularity of the opening in the third region be twice that of the first and second regions or better, actual fabrication can be performed easily even though the thickness of the third region is larger than those of the first and second regions.

With the charged particle beam lens according to the present invention, a step of forming openings in the first and second regions, for which high precision is required, may be performed independently of a step of forming an opening in the third region. In this case, by using semiconductor manufacturing technologies, fine and high precision openings can be formed while improving controllability of etching conditions and the yield. In particular, an electrode having a finer opening can be formed with high precision by using microfabrication technologies, such as photolithography or dry etching, and wafer bonding through silicon wafers having high degree of flatness. Thus, an electrostatic charged particle beam lens having an opening that has a diameter in the order of several tens of micrometers and a circularity in the order of nanometers can be formed. As necessary, the electrode may have a stacked structure in which a plurality of wafers are bonded. For example, because precision of forming an opening generally decreases as the thickness of a wafer increases, the thickness of a single wafer may be determined in accordance with a required precision (the thickness is reduced when higher precision is required). In this case, if the thickness of the entirety of the electrode becomes insufficient, a plurality of wafers may be stacked. Instead of stacking wafers, an electrode may be formed by depositing necessary layers by using, for example, a spattering method, a CVD method, a vapor-phase or liquid phase epitaxial growth method, or a plating method.

With the charged particle beam lens according to the present invention, fluctuation of a charged particle beam due to an unintentional charge can be prevented by covering the entirety of the electrode with an electroconductive film as necessary and thereby maintaining the potential of the electrode to be constant.

The charged particle beam lens according to the present invention may be formed as a charged particle beam lens array including an electrode having a plurality of openings. Because the opening cross sections of the first and second regions, whose contributions to the aberration of the lens are high, can be fabricated with high precision, variation in the circularities of the opening cross sections of individual lenses of the lens array can be reduced. In the case of a lens array, it is difficult to correct the circularity of each of the individual lenses because the circularity has a random error. However, because variation in the circularity of the opening cross section can be reduced by using the present invention, necessity for individual correction can be eliminated or considerably reduced even for a large-scale lens array. Moreover, when an electrode having a bonding structure is used, variation in the opening cross sections can be sufficiently reduced. If the alignment precision of bonding is low, displacement between the openings of the first and second regions occurs. However, this displacement can be easily corrected because it is a systematic displacement in the entirety of the lens array. Therefore, this structure is appropriate for a large-scale lens array.

An exposure apparatus according to the present invention includes the charged particle beam lens according to the present invention having a small aberration, so that the exposure apparatus can form a fine pattern with high precision.

The exposure apparatus according to the present invention may use a plurality of charged particle beams by using the charged particle beam lens according to the present invention having a small aberration, so that the exposure apparatus can form a fine pattern with high precision in a short time.

### Embodiments

Hereinafter, embodiments of the present invention will be described in detail. However, the present invention is not limited to these embodiments.

### First Embodiment

A first embodiment of the present invention will be described.

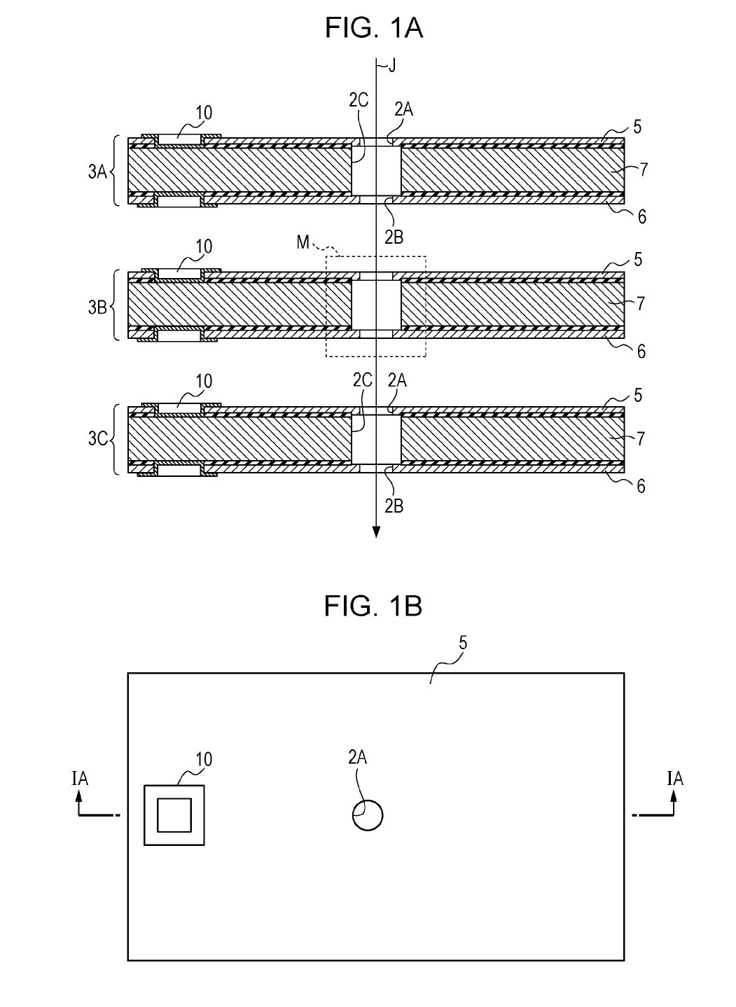

FIG. 1A is a sectional view of a charged particle beam lens according to the present invention taken along line IA-IA of FIG. 1B. FIG. 1B is a top view of the charged particle beam lens.

As illustrated in FIG. 1A, the charged particle beam lens according to the present invention includes three electrodes 3A, 3B, and 3C. Each of the three electrodes is a flat plate having the optical axis J as a normal line and including a first surface and a second surface opposite to the first surface. The electrodes are electrically insulated from one another. The first surface is typically the front surface, and the second surface is typically the back surface. Here, the terms “front” and “back” are used only to denote a relative relationship for convenience. Each of the electrodes 3A, 3B, and 3C includes an electrode pad 10 through which the potential of the electrode is controlled. A charged particle beam emitted from a beam source (not shown) passes along the optical axis J in the direction indicated by an arrow. The length of an electrode in the direction of the optical axis j will be referred to as a thickness.

Each of the three electrodes includes three regions having predetermined thicknesses, which are a first region 5, a second region 6, and a third region 7 disposed between the first and second regions. Here, it is assumed that a thickness of an electrode is the length of the electrode in the direction of the optical axis J. As illustrated in FIG. 1A, the first region 5 includes the entire surface of the electrode on the beam source side with respect to the direction of the optical axis J and has a predetermined thickness. Likewise, the second region includes the entire surface of the electrode on a side opposite to the beam source side with respect to the direction of the optical axis J and has a predetermined thickness. The third region, which is disposed between the first and second regions, is the remaining region of the electrode and has a predetermined thickness.

The first, second, and third regions 5, 6, and 7 respectively include openings 2A, 2B, and 2C. As illustrated in FIG. 1A, the openings 2A, 2B, and 2C are through-holes extending through the electrodes in the thickness direction. A charged particle beam can pass through the openings (and the through-hole). As illustrated in FIG. 1B, the opening 2A has a circular shape. Likewise, when an opening cross section is defined as a section of an opening taken along a plane having the optical axis J as a normal line, opening cross sections of the openings 2B and 2C have circular shapes that are concentric with that of the opening 2A. The diameter of the opening cross section of the opening 2C is larger than those of the openings 2A and 2B. Therefore, as illustrated in FIG. 1A, the through-hole formed in each of the electrodes 3A, 3B, and 3C has a profile such that the diameter thereof is smaller at the entrance and the exit. Here, the optical axis extends in a direction in which the electron beam passes.

For example, a so-called einzel electrostatic lens is formed by applying a negative static voltage to the electrode 3B while maintaining the potential of the electrodes 3A and 3C at the ground potential. In the present invention, the term “einzel electrostatic lens” refers to an electrostatic lens in which a plurality of (typically, three) electrodes are arranged with predetermined intervals therebetween and in which the potential of outermost electrodes are maintained at the ground potential and a positive or negative potential is applied to other electrodes. When three electrodes are used, the first and the third electrodes from the incident side of a charged particle beam are maintained at the ground potential, and a positive or negative potential is applied to the second electrode. A charged particle beam is subjected to a lens effect while the beam successively passes through the openings in the electrodes 3A, 3B, and 3C. At this time, an electrostatic attraction force is generated between the electrodes 3A and 3B or between the electrodes 3B and 3C.

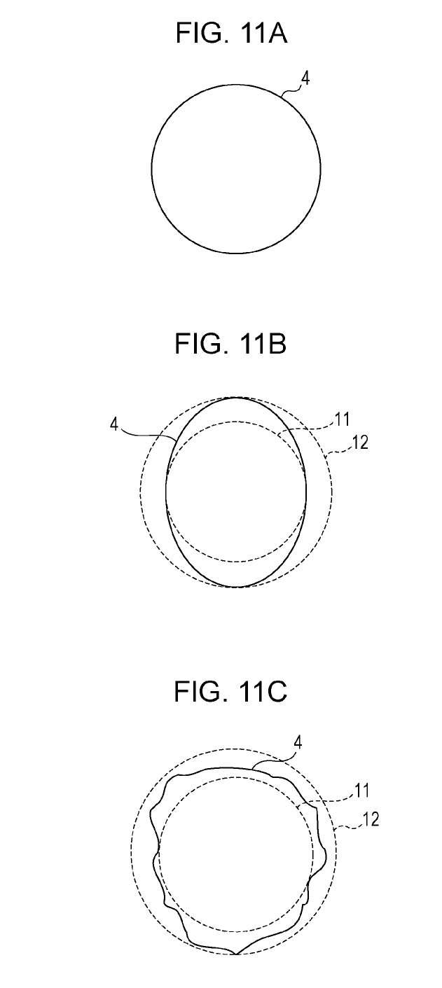

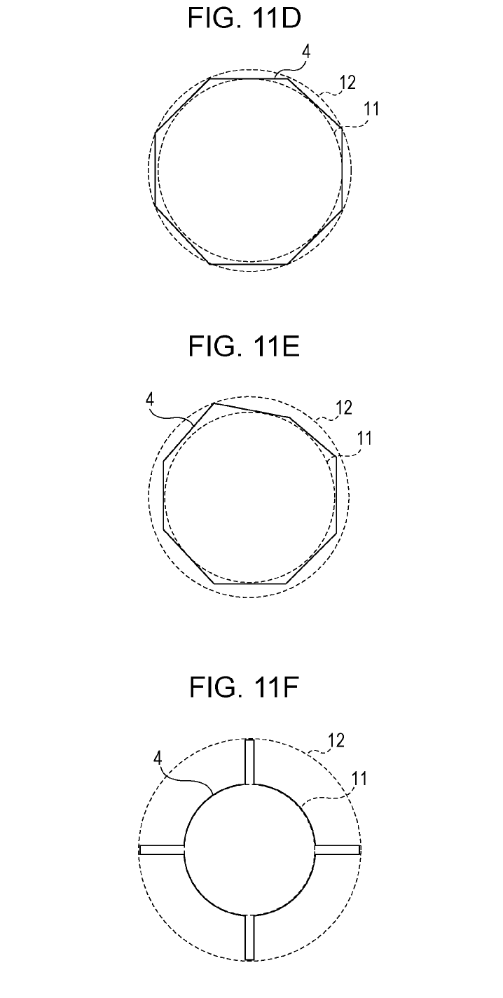

First, referring to FIGS. 11A to 11F, the definition of the symmetry of an opening cross section, which is necessary for describing a charged particle beam lens according to the present invention, will be described. An electrostatic field that generates a lens effect of an electrostatic charged particle beam lens is formed by the opening cross section. In particular, because astigmatism and higher order aberrations are generated due to rotational asymmetry around the optical axis J, deviation from a perfect circle is an important index.

FIG. 11A illustrates an opening cross section 4 having an ideally circular shape (perfect circle). Here, an opening cross section is a closed curve that is the intersection of an opening and a plane having the optical axis J as a normal line. An opening cross section can be defined at any position along the thickness direction. FIG. 11B illustrates an opening cross section 4 having an elliptical shape. The following index is defined as a measure of a shape error that influences the astigmatism and higher order aberrations of a charged particle beam lens according to the present invention. The opening cross section 4 illustrated in FIG. 11B, which has an elliptical shape, is disposed between two concentric circles so as to be in contact with the concentric circles. The inner circle will be referred to as an incircle 11, and the outer circle will be referred to as a circumcircle 12. Among many combinations of such concentric circles that can be drawn around different centers, a pair of an incircle and a circumcircle between which the difference in the radii thereof is the smallest are selected. The circularity is defined as a half the difference in the radii of the incircle and the circumcircle that are selected in this way. For the opening cross section 4 having a perfectly circular shape as illustrated in FIG. 11A, the circularity is zero because the circumcircle and the incircle coincide with each other.

As illustrated in FIG. 11C, the circularity is defined in a similar manner for any shapes other than ellipse.

The ideal shape in terms of design may not be a circular shape but a polygonal shape as illustrated in FIG. 11D. (An octagonal shape used as an example in the following description.) In this case, the circularity, the representative radius (described below), and the representative diameter (described below) are defined by the following method. That is, deviation of symmetry from an ideal octagon and the size of the opening can be compared by defining the circularity, the representative radius, and the representative diameter. FIG. 11D illustrates the circumcircle 12 and the incircle 11 of an ideal octagon. In the case of an octagon, the circularity is equal to or larger than zero even in an ideal state. FIG. 11E illustrates the circumcircle 12 and the incircle 11 of an octagon that has a shape error and that is deviated from a regular octagon. Therefore, the circularity in the case of FIG. 11E is larger than that of FIG. 11D, which is the case of a regular octagon.

The circularity can be defined by actually measuring the sectional shape. The sectional shape can be calculated by dividing the perimeter into a sufficiently large number of segments if possible and obtaining the circumcircle 12 and the incircle 11 through image processing.

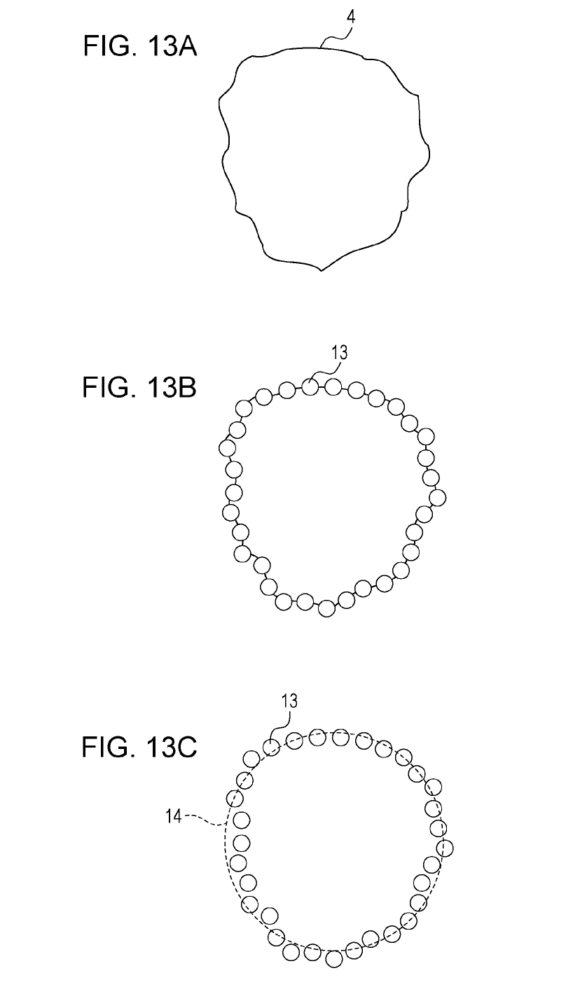

The representative diameter and the representative radius are defined as follows. FIGS. 13A to 13C illustrate steps for determining the representative diameter of an opening cross section 4 of FIG. 11C. The outline of the opening cross section 4 of FIG. 13A is measured as a set of discrete measurement points 13 that are spaced apart from each other with sufficiently small intervals therebetween as illustrated in FIG. 13B. The intervals may be smaller than half the representative period of the asperity of the opening cross section 4. By using the measurement points 13 having been measured in this way, a representative circle 14 is uniquely determined as illustrated in FIG. 13C. Regression analysis is performed by using the measurement points 13 so that these points are geometrically fitted to an equation of a circle. The regression analysis may be performed by using a maximum likelihood method. If the measurement points 13 are measured with sufficiently small intervals, the method of least squares can be used. The representative diameter and the representative radius are defined as the diameter and the radius of the representative circle 14 that is determined in this way. The representative diameter and the representative radius of a representative circle are important as the representative shape that determines the distribution in the potential on or near the optical axis, because a charged particle beam passes through the center of the opening.

FIG. 11F illustrates an opening cross section 4 most parts of which are circular and the remaining parts have protruding shapes. Even in this case, the representative diameter and the representative radius can be obtained by determining a representative circle, which is a representative shape that contributes to the electric field in the vicinity of the optical axis, by using the method described above. When such a circle is obtained, the circumcircle 12 and the incircle 11 are defined by drawing circles that are concentric with the circle that has been obtained by performing geometric fitting.

On the basis of the definition described above, the circularity, the representative radius, and the representative diameter are defined for an arbitrary opening cross section. Hereinafter, a circle is used as the ideal shape of an opening cross section. However, the ideal shape may be an octagon or any other curve. Also in such cases, the circularity, the representative radius, the representative diameter can be defined and used in the present invention.

Next, the effect of the circularity of an opening cross section on the aberration will be described.

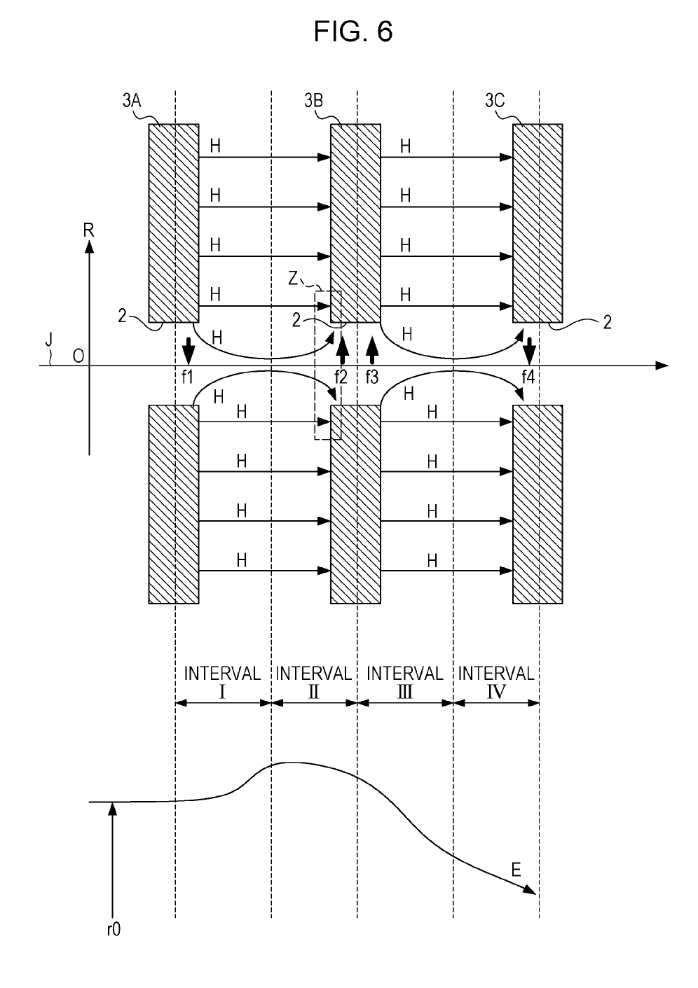

First, referring to FIG. 6, mechanisms with which an electrostatic charged particle beam lens converges a charged particle beam will be described. In FIG. 6, an R-axis extends in the radial direction of the lens, a J-axis extends in the optical axis direction, and “O” denotes the origin. FIG. 6 is a sectional view of an einzel lens taken along a plane parallel to the J-axis. The einzel lens includes three electrodes 3A, 3B, and 3C. The potential of the electrodes 3A and 3C are maintained at the ground potential, and a negative potential is applied to the electrode 3B. A charged particle beam has a negative charge. The three electrodes 3A, 3B, and 3C are flat plates each having the optical axis J as a normal line.

Electric flux lines generated in this state are illustrated by solid-line arrows H. The mid-planes of the three electrodes 3A, 3B, and 3C in the X direction and the mid-planes of spaces between the three electrodes are illustrated by broken lines. Intervals between broken lines along the J-axis will be referred to as an interval I, an interval II, an interval III, an interval IV. For convenience of describing the main lens effect of the einzel lens, it is assumed that an interval on the origin O side of the interval I and an interval on a side of the interval IV opposite to the origin O side are not provided with a potential.

The directions of electric fields in the interval I, the interval II, the interval III, and the interval IV in a region where R>0 are respectively indicated by arrows f1, f2, f3, and f4. The directions of the electric fields in the interval I, the interval II, the interval III, and the interval IV are respectively negative, positive, positive, and negative. Therefore, the path of a charged particle beam that passes an image height r0 is as indicated by arrow E. That is, the charged particle beam is diverged in the interval I, converged in the interval II, converged in the interval III, and diverged in the interval IV. This is optically equivalent to a concave lens, a convex lens, a convex lens, and a concave lens that are arranged in the X-axis direction.

The charged particle beam is converged for the following two reasons. A first reason is that, because a stronger force is applied to the charged particle beam at a larger image height, the effect of convergence in the interval II and the interval III is larger than the effect of divergence in the interval I and the interval IV. A second reason is that the charged particle beam travels in the interval II for a time longer than that in the interval I and travels in the interval III for a time longer than that in the interval IV. Because a change in momentum is equal to an impulse, a larger effect occurs on the electron beam in the intervals that take a longer time for the electron beam to travel.

The convergence effect is generated for the reasons described above. The charged particle beam is converged in a similar manner when a positive potential is applied to the electrode 3B. A charged particle beam having a positive charge is also converged. The convergence effect occurs for any combinations of the positive/negative potential of the electrode 3B and the positive/negative charge of the charged particle beam. If the symmetry of the convergent field is broken due to a shape error in the opening 2 that forms the electric fields in the intervals I to IV, the electrostatic lens has high order aberrations such as astigmatism. Therefore, it is necessary that the shape of the opening be accurately formed, because the aberration of the electrostatic charged particle beam lens is sensitively influenced by the shape error in the opening formed in the electrode.

The thicker the electrode in which an opening is to be formed, the more difficult it is to reduce the shape error of the opening. When the electrode has a large thickness, it is difficult to control the shape error of the opening at the front and back surfaces and through the inside of the electrode. As a result, the fabrication cost increases or the fabrication may become difficult if the required precision is high. In order to reduce the difficulty in the fabrication, a thinner electrode may be used. However, if the thickness of the electrode is simply reduced, the electrode may become deformed due to an electrostatic attraction force that is generated by a voltage applied to the electrode. In order to reduce the aberration of the electrostatic lens, it is also necessary to reduce the spherical aberration of the lens by decreasing the focal length of the lens. In this case, however, a strong electric field is generated between the electrodes, so that deformation of the electrodes due to the electrostatic attraction force causes a major problem. If deformation of an electrode occurs, an error in the distance between electrodes is generated, the opening may become inclined with respect to the optical axis J, and thereby the symmetry of the shape of the opening, which influences the lens effect of the charged particle beam, may become broken as described below. As a result, although the spherical aberration is reduced, higher order aberrations may increase, or in the case of a lens array having a plurality of openings in one electrode, variation in the focal lengths of individual lenses may occur.

Therefore, if the contribution of the circularity of the opening cross section in a portion through which the opening extends with a large thickness can be reduced, the aberration of the lens can be reduced without increasing the difficulty of forming the through-hole.

In the charged particle beam lens according to the present invention, an opening through which a charged particle lens passes is segmented into the opening 2A in the first region, the opening 2B in the second region, and the opening 2C in the third region, and the representative diameter of the opening 2C is larger than those of the openings 2A and 2B. With such segmentation of the opening, the contribution of the opening 2C on the aberration is reduced, and the influence of this portion on the aberration of the lens can be reduced even if the opening cross section in this portion is bad.

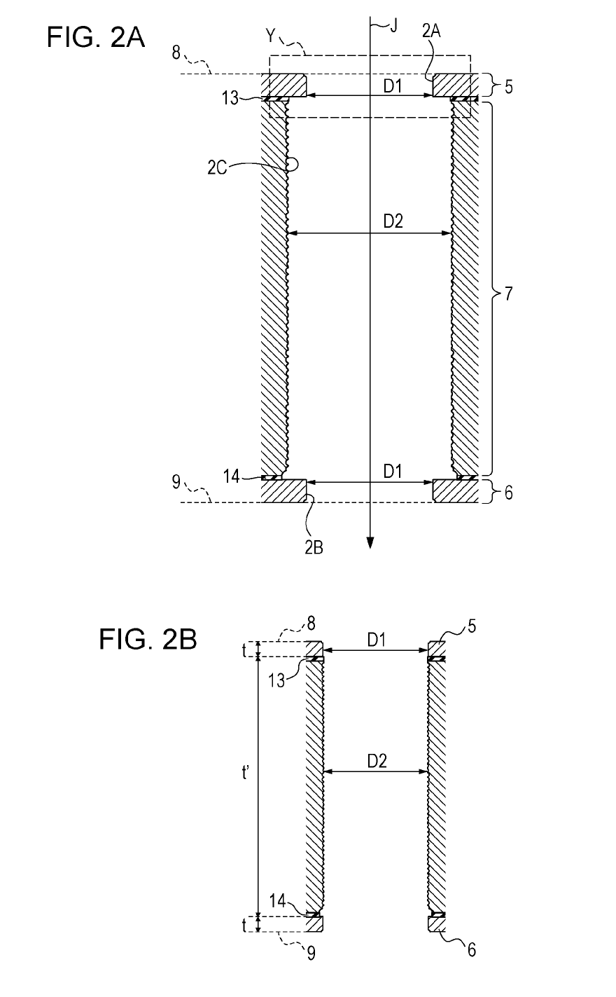

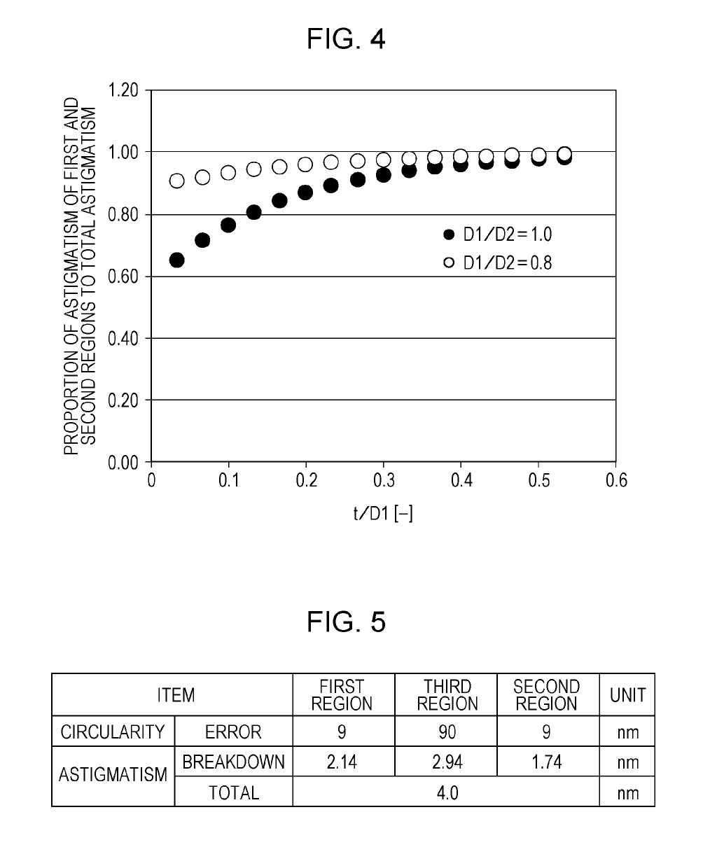

Next, referring to FIGS. 2A, 2B, and 4, the fact that the influence of the circularity of the opening 2C in the third region on the total astigmatism can be reduced by using a relationship between the representative diameters according to the present embodiment will be described.

FIG. 2A is an enlarged sectional view of a portion of the electrode 3B according to the present embodiment surrounded by broken line M in FIG. 1A. As illustrated in FIG. 2A, the opening 2A in the first region 5, the opening 2B in the second region, and the opening 2C in the third region respectively have representative diameters D1, D1, and D2. Here, a surface of the first region 5 on the free side is the first surface of the electrode 3B and a surface of the second region 6 on the free side is the second surface. That is, the electrode 3B has the first surface and the second surface opposite to the first surface. As described above, D1<D2. The thicknesses are respectively t, t, and t′. The electrode 3B has a structure bonded through a first interface 13 and a second interface 14. The first region 5 includes the first surface 8, which corresponds to the outermost surface of the electrode 2B having the optical axis J as a normal line. The second region includes the second surface 9, which corresponds to the outermost surface of the electrode 2B opposite to the first surface 8 and having the optical axis J as a normal line. FIG. 2B illustrates a case where the representative diameters D1 and D2 are the same, which is the case of an existing technology. As illustrated in the figures, FIG. 2B illustrates a structure the same as that of FIG. 2A except for the relationship between the representative diameters D1 and D2.

FIG. 4 illustrates the proportion (contribution) of the sum of the aberrations of the openings 2A and 2B in the astigmatism of the lens in the cases of FIGS. 2A and 2B. The horizontal axis represents the ratio of the diameter D1 and the thickness t of the openings 2A and 2B. Solid circles represent the case where the diameters D1 and D2 are the same.

In the case where the diameters D1 and D2 are the same, the thickness t of the openings 2A and 2B is ⅛ of the diameter D1, and the sum of the aberrations of the openings 2A and 2B can occupy 80% of the total aberration. Because there is a small difference between the openings 2A and 2B, the contributions of the openings 2A, 2B, and 2C are 44%, 36%, and 20%, respectively.

Open circles in FIG. 4 represent the case of the present embodiment where the diameter D1 is 0.8 times the diameter D2. In the case where the diameter D1 is 0.8 times the diameter D2, as compared with the case where the diameters D1 and D2 are the same, the contributions of the openings 2A and 2B are high even when the thickness t is small. When the thickness t is ⅛ of the diameter D1, the contribution is about 94%. When the thickness t is ⅕ of the diameter D1, the contribution is 96%. Thus, in particular in a region where D1<D2, the contributions of the openings 2A and 2B can be further increased.

The relationship between the contributions does not change even when the thickness t′ of the opening 2C is changed. Therefore, by increasing the thickness of the opening 2C, the thickness of the entirety of the electrode can be increased while maintaining the relationship between the contributions. In this case, because the contributions of the openings 2A and 2B on the aberration is high, the influence on the aberration of the entirety of the lens can be reduced even if the opening 2C has a large manufacturing error.

Hereinafter, mechanisms with which the contribution to the aberration is considerably influenced by the opening cross sections at positions near the surfaces, such as the opening 2A and 2B, and the relationship between the thickness of the flat plate in which the opening is formed and the circularity of the opening cross section will be described in this order.

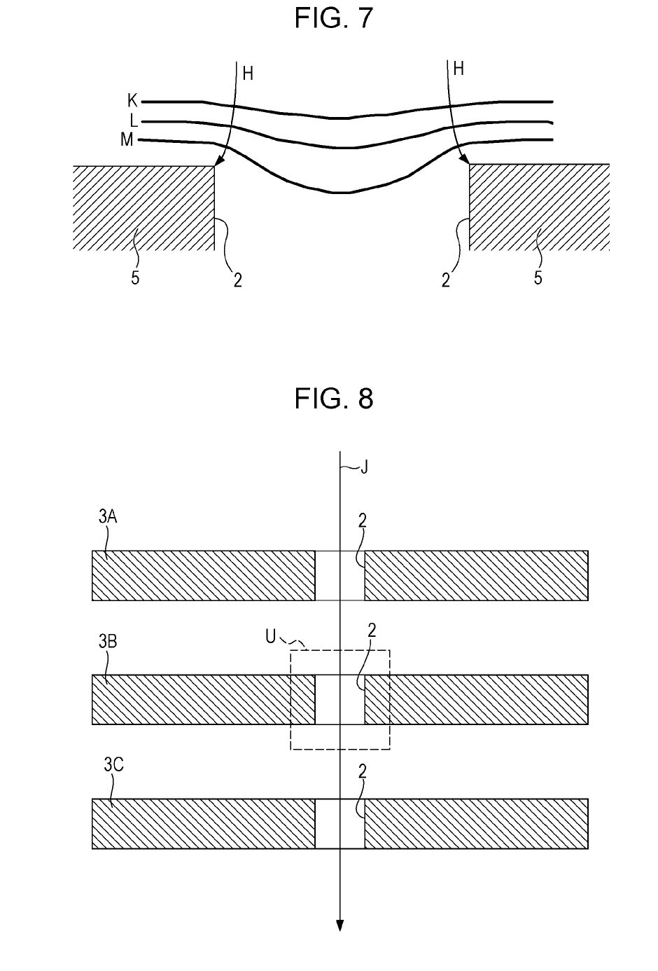

Referring to FIG. 7, the fact that the contribution of the shape of the opening to the aberration decreases as a position moves deeper in the through-hole from positions near surfaces of the first region and the second region such as positions at the openings 2A and 2B. FIG. 7 is an enlarged view of a region surrounded by broken line Z in FIG. 6. Curves K, L, and M represent equipotential lines in a space near a surface of an opening 2 in the electrode 3B. Curves H represent electric flux lines corresponding to an outermost surface of the opening 2. As illustrated in FIG. 7, the curves K, L, and M are substantially parallel to the surface of the electrode 3B in regions outside of the electric flux lines H (that is, on the sides on which the opening 2 is not formed). Therefore, the electric flux lines in this region are substantially parallel to a normal line of the electrode. Therefore, the influence of the shape of the electrode in this region on the electric fields in the R direction (see f1, f2, f3, and f4 in FIG. 6), which produce a lens effect, is negligibly small.

On the other hand, the equipotential lines K, L, and M are curved toward the inside of the opening 2 in regions inside of the electric flux lines H (that is, on the sides on which the opening 2 is formed). Therefore, the electric flux lines H and electric flux lines inside the electric flux lines H form the electric fields in the R direction, which produce a lens effect as described with reference to FIG. 6. Three-dimensionally, a charged particle beam is influenced by the electric fields in the R direction, which are illustrated in FIG. 6 and produce a lens effect, in all circumferential directions around the center of the optical axis J in a plane having the optical axis J as a normal line. The symmetries of the electric flux lines H and the electric flex lines inside the electric flux lines H in the circumferential direction (i.e. the circularity of a circular shape) around the optical axis J are influenced by the symmetry of the shape of a cross section of the opening 2 taken along a plane having the optical axis J as a normal line. The distances between the equipotential lines K, L, and M increase toward the optical axis J of the opening 2. The density of the electric flux lines decreases in a direction inward from the electric flux lines H and in a direction deeper in the thickness direction. Therefore, the sectional shape of the opening 2 at the outermost surface of the electrode influences most significantly to the convergence of a charged particle beam and the influence decreases as the depth in the thickness direction increases.

Here, the direction f2 of the electric field in the interval II of FIG. 6 has been described in detail. For the same reason, regarding each of the directions f1, f3, an f4 of the electric fields in the intervals I, III, and IV, the sectional shape of the opening 2 at the outermost surface of the electrode influences most significantly to the convergence of a charged particle beam. Therefore, the influence decreases with increasing distance from the outermost surface.

Even if the depth of the opening is increased, the contribution of the opening cross section near the surfaces does not change. That is, the thickness of the opening 2C can be increased without changing the contribution of the openings 2A and 2B to the aberration. Because the circularity of the opening cross section of the opening 2C has only a small contribution to the aberration due to the relationship D1<D2 between the representative diameters of the present embodiment, the thickness and the rigidity of the entire electrode can be increased while restraining increase in the aberration.

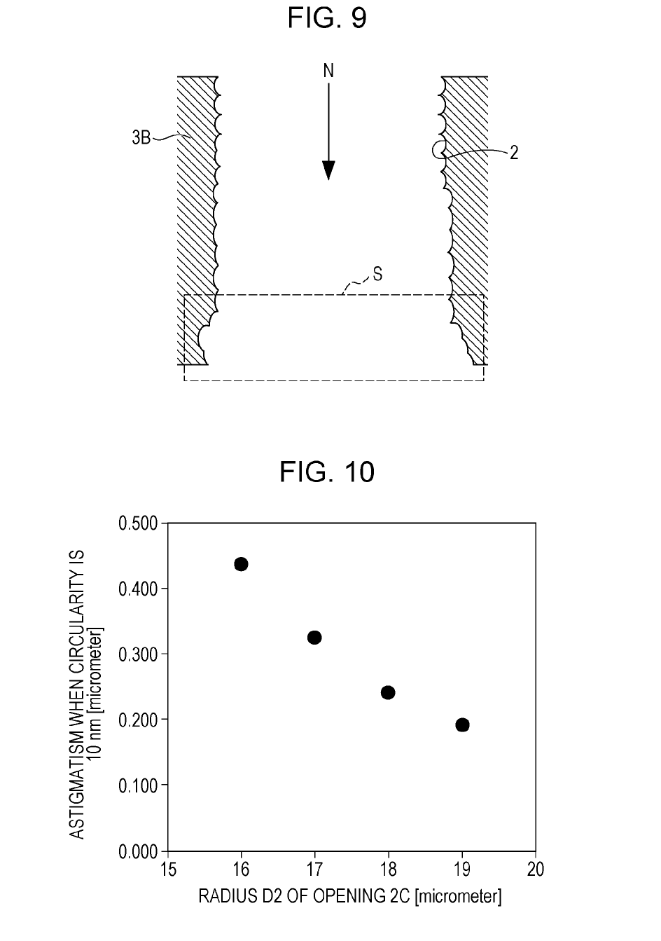

Referring to FIGS. 8 and 9, the relationship between circularity and a process of forming a through-hole in a flat plate will be described. FIG. 8 is a sectional view of a charged particle beam lens including flat plates of monocrystalline silicon as the electrodes 3A, 3B, and 3C. As in the case of FIG. 1A, each electrode has an opening 2 through which a charged particle beam passes. FIG. 9 is an enlarged sectional view of a portion surrounded by broken line U in FIG. 8.

FIG. 9 illustrates a sectional shape that is formed by performing deep dry etching of monocrystalline silicon so that an opening extends through the substrate in the direction of arrow N. In a deep dry etching process, etching is performed while alternately supplying an etching gas and a shielding gas. Therefore, as illustrated in FIG. 9, a small asperity called a scallop is formed on a side surface. As etching progresses, error factors that influence the asperity, such as supply and exhaust of the etching gas and the shielding gas and heat due to chemical reaction, increase. Therefore, the depth and pitch of the asperity is changed depending the position, and thereby the circularity may become worse. Moreover, it is known that, just before an opening extends through the substrate, the path of the etching gas is bent due to the presence of an interface in a direction in which the opening is being formed, and thereby a phenomenon called “notching”, with which the opening is widened as shown by a region surrounded by broken line S, occurs. Due to these effects, the circularity of such an opening becomes worse in the direction of arrow N. Therefore, the circularity of the region surrounded by broken line S is the worst. The deeper the etching depth in the opening, the more frequently side etching occurs at an edge portion (not shown) of an etching mask at the etching start surface (the surface near the tail of arrow N), and thereby the opening shape of the etching mask becomes deformed. Therefore, the circularity becomes worse. As described above, when forming an opening in a flat plate, the circularity becomes worse as the thickness of the flat becomes larger.

With the present embodiment, even when the thickness of the opening 2C is increased, the contribution of the opening cross section in this portion to the aberration is small. Therefore, increase in the aberration of the lens can be restrained even if the precision of forming an opening having a high circularity cannot be improved due to the increased thickness.

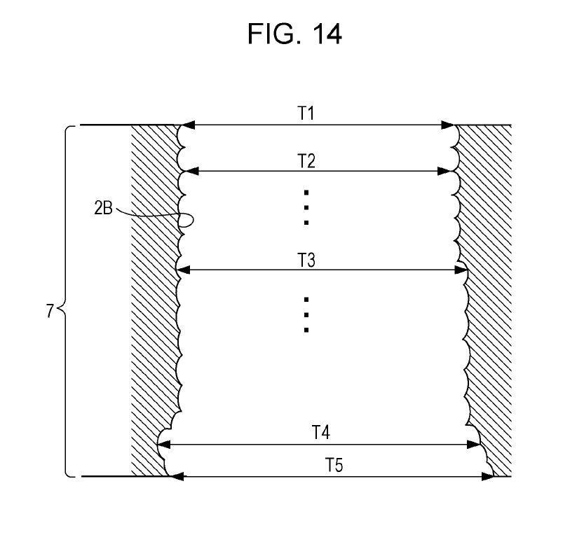

Next, the circularity of an opening cross section in the first to third regions in the thickness direction will be described. FIG. 14 illustrates a through-hole formed by performing deep dry etching of silicon as illustrated in FIG. 9 in the third region 7 of FIG. 2A. FIG. 14 illustrates only the third region 7. As indicated by arrows T1 to T5 in FIG. 14, opening cross sections can be defined at any positions along the depth direction. The representative diameter and the circularity describe above can be defined for each of these opening cross sections. Here, the representative diameter and the circularity of the third region 7 can be defined in this way at any positions in the depth direction of the opening. The representative diameter and the circularity of a part of the region excluding the outermost surface (also called a free surface) can be measured by temporarily backfilling the opening with plating or the like and polishing and then observing the opening. Alternatively, instead of performing such direct measurement, measurements of the outermost surface may be used as the representative value. Parts of the first to third regions other than the outermost surfaces are those that contribute to the aberration with a smaller degree. Therefore, as compared with the outermost surfaces, change in the representative diameter and the circularity of these parts in the same order of magnitude influences the aberration with a smaller degree. Therefore, if the measured values of the representative diameter and the circularity at several sections of the opening in the thickness direction do not have a distribution of the values including outliers having a different order of magnitude, the average of the representative diameters and the circularities at the outermost surfaces (i.e., at positions T1 and T5 in FIG. 14) can be used as the representative value.

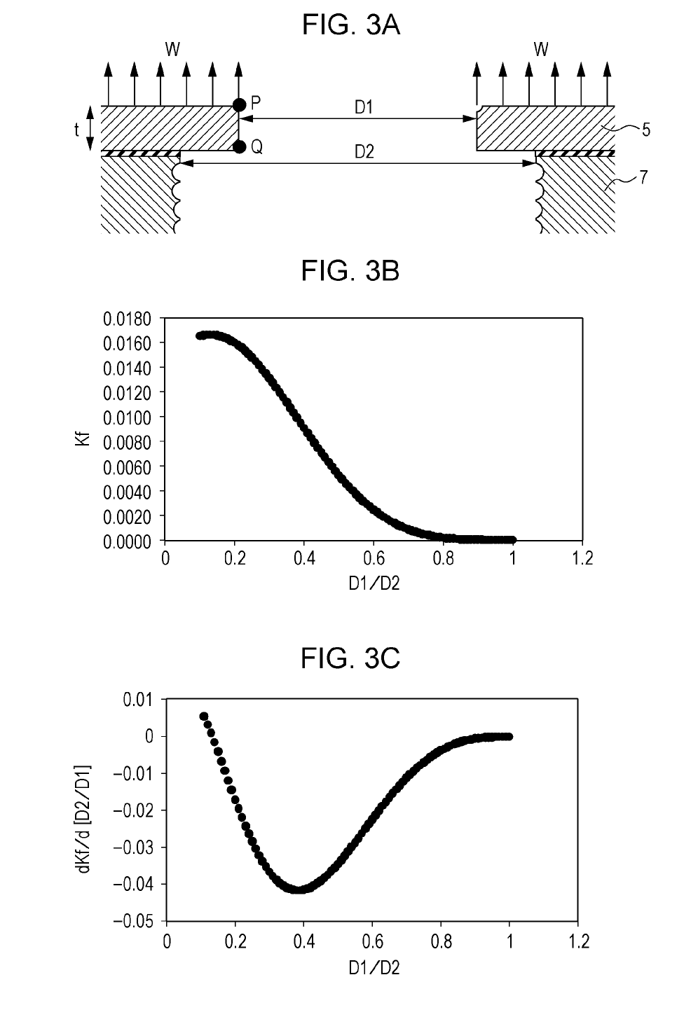

Next, referring to FIG. 3, a more appropriate range of the diameters D1<D2 will be described. FIG. 3A is an enlarged view of a region surrounded by broken line Y in FIG. 2A. The electrodes 3A and 3C illustrated in FIG. 1A are maintained at the ground potential and a negative potential is applied to the electrode 3B. Therefore, an electrostatic attraction force is generated at the upper surface of the first region 5. Hereinafter, this electrostatic attraction force will be regarded as a distributed load w as an approximation.

When D1<D2, the first region 5 has a protruding portion that protrudes in a ring shape into the third region as illustrated in FIG. 3A. When the protruding portion receives an electrostatic attraction force, the protruding portion becomes deformed in the direction of the distributed load w. A deformation y of an end face of the protruding portion (represented by line segment PQ in FIG. 3A, which is a sectional view) in the direction of the distributed load can be expressed by the following equations.

$$\begin{matrix}[ Math . 1 ] & \\ y = {K}_{f} \cdot \frac{w \cdot {D}_{2}^{4}}{16 D} & ( 1 ) \\ [ Math . 2 ] & \\ D = \frac{E \cdot {t}^{3}}{12 ( 1 - {v}^{2} )} & ( 2 )\end{matrix}$$

(E is Young's modulus and v is Poisson's ratio.)

The coefficient Kf in equation (1) is a function of the ratio of the diameter D1 and the diameter D2 and is a coefficient of a shape factor of the diameters D1 and D2 in the rigidity of the ring-shaped protruding portion. The coefficient Kf is a proportionality coefficient of the displacement y. Therefore, the larger the coefficient Kf, the lower the rigidity.

FIG. 3B plots the coefficient Kf as a function of the ratio of the diameters D1 and D2. As D1/D2 approaches 1 (i.e. as the protruding portion becomes smaller), the rigidity increases. FIG. 3C plots the derivative function of the coefficient Kf with respect to D1/D2. The differential coefficient of the coefficient Kf has a minimal value near D1/D2=0.4.

In the vicinity of the minimal point of the differential coefficient of Kf, the rate of change of the coefficient Kf to a change in D1/D2 is the largest. That is, if D1/D2 changes due to a fabrication error, the rigidity changes by a large amount. Therefore, the displacement y of the protruding portion changes by a large amount. If the displacement varies due to a fabrication error in this way, the circularity of the opening 2A may vary or the effective diameter D1 may vary due to the deformation. In the case of a lens array including an electrode having a plurality of openings, the differences between the deformations of openings may become larger.

Therefore, D1/D2 may be larger than 0.4 and smaller than 1.0. In this range, the coefficient Kf and the absolute value of the differential coefficient of the coefficient Kf are small in the region, and thereby both deformation of the protruding portion and variation in the deformation due to a fabrication error of the opening can be reduced.

If D1/D2 is equal to or larger than 0.8 and smaller than 1.0, the deformation and the variation in the deformation can be reduced further. In particular, in the range where D1/D2 is equal to or larger than 0.8 and smaller than 1.0, D1/D2=0.8 is the value at which the aberration can be made to be the smallest.

Next, specific examples of the materials and the dimensions of the present embodiment will be described. The first, second, and third regions of each of the electrodes 3A, 3B, and 3C are made from monocrystalline silicon. The thicknesses of the first, second, and third regions are respectively 6 micrometers, 6 micrometers, and 90 micrometers. The diameter D1 of the openings 2A and 2B is 30 micrometers, and the diameter D2 of the opening 2C is 36 micrometers. The electrode pad 10 is made from a metal film that has good adherence to silicon, high conductivity, and resistance to oxidization. For example, multilayer film made from titanium, platinum, and gold can be used. Silicon oxide films are formed at the interfaces 13 and 14. All of the first and second surfaces 8 and 9 and the inner walls of the openings 2A, 2B, and 2C of the electrodes 3A, 3B, and 3C may be covered by metal films. In this case, a metal such as a platinum metal that is resistant to oxidization or a molybdenum oxide having electroconductivity can be used. The electrodes 3A, 3B, and 3C are disposed so as to be separated from each other with a distance of 400 micrometers therebetween and so as to be parallel to a plane having the optical axis J and a normal line. The electrodes are electrically insulated from each other. The ground potential is applied to the electrodes 3A and 3C, and a potential of −3.7 kV is applied to the electrode 3B, so that the electrodes serve an einzel lens. FIG. 5 is a table showing the astigmatism of the electrode 3B according to the present embodiment when an electron beam is used as a charged particle beam and the acceleration voltage is 5 keV. The circularity of the opening 2A and 2B is 9 nm, and the circularity of the opening 2C is 90 nm. As illustrated in the table, the breakdown of the astigmatism is 2.14 nm, 2.94 nm, and 1.74 nm. Although the circularity of the opening 2C is 10 times that of the openings 2A and 2B, the astigmatism of the entire electrode 3B is 4.0 nm. (The values of the astigmatism are all represented as 1/e radius of the Gaussian distribution.) This corresponds to the astigmatism in the case where the diameters of the openings 2A, 2B, and 2C are all 30 micrometers and the circularity of the sectional shape over the entire thickness of 100 micrometers is 9 nm.

Portions of the openings in which high circularity (corresponding to a circularity of 9 nm) is required may be formed in a thin plate a thickness of 6 micrometers. Therefore, difficulty in the fabrication can be reduced, and a circular opening having an error in the circularity as small as 9 nm can be formed all along the opening. Although it is necessary to form a through-hole having a thickness of 90 micrometers in a region of the opening 2C to maintain the rigidity, the difficulty in fabrication is not increased because the circularity of this portion may be 10 times worse.

Referring to FIG. 10, the fact that the astigmatism decreases with an increasing diameter of the opening 2C in the third region 7 will be described. FIG. 10 illustrates the relationship between the diameter of the opening 2C and change in the astigmatism. The astigmatism corresponds to the case where the circularity of the opening cross section of the opening 2C is 10 nm. FIG. 10 illustrates values of the astigmatism due to the opening 2C when the openings 2A and 2B have ideally circular shape. As can be seen from FIG. 10, as D2 increases, the astigmatism decreases. Therefore, by increasing the value of D2 while maintaining D1<D2, the sensitivity of the astigmatism to the circularity of the opening 2C can be reduced. Thus, even if the circularity of the opening cross section in the opening 2C is bad, by setting D2 while maintaining the relationship D1<D2, a charged particle beam lens having a small aberration can be manufactured.

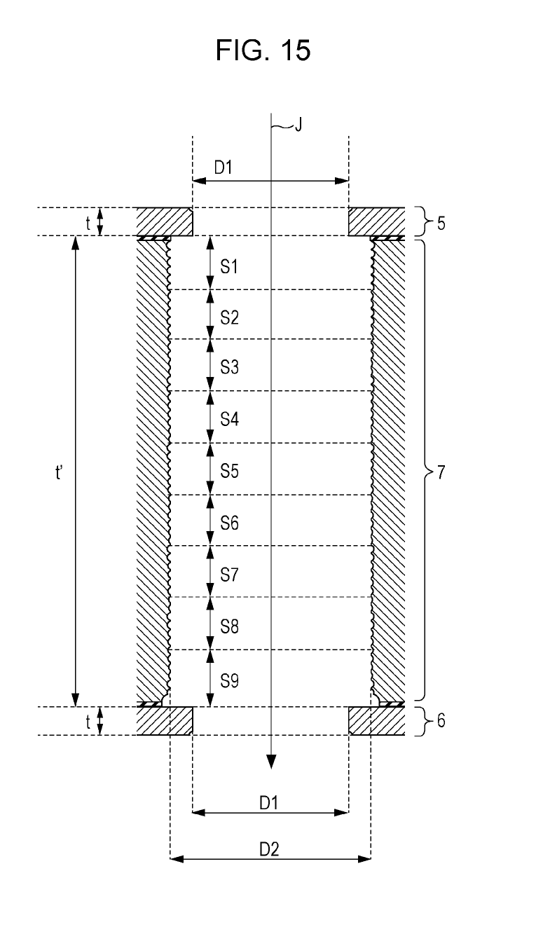

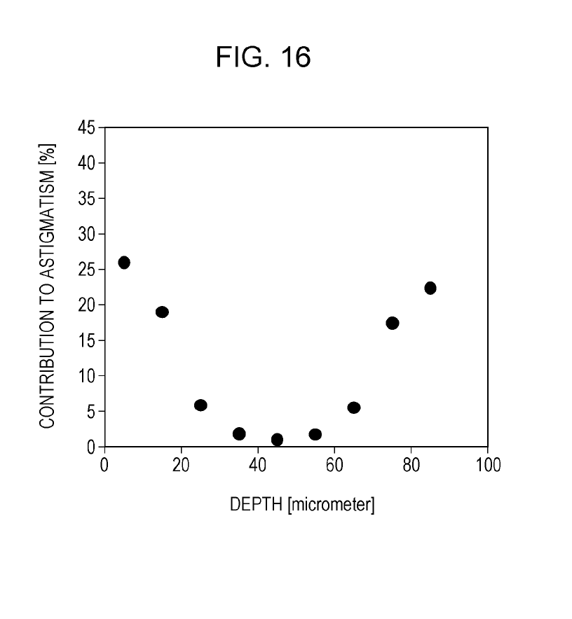

Next, the relationship between the distribution of the circularity of the third region 7 in the thickness direction and the contribution of aberration will be described. As illustrated in FIG. 15, which illustrates an opening in the electrode 2B in the design example described above, the third region 7 is segmented into regions S1 to S9 each having a length of 10 micrometers in the thickness direction. When these regions have different circularities, the sensitivity of astigmatism to the circularity is analyzed. In FIG. 16, the horizontal axis represents the positions of the regions S1 to S9 in the depth direction (the depth at the center of each region is used as the representative position) and the vertical axis represents the proportion (contribution) of the aberration of the region to the aberration of the entirety of the third region 7. That is, FIG. 16 shows the influences of the regions S1 to S9 on the astigmatism when the circularities of these regions are the same. As can be seen from FIG. 16, about 84% of the aberration is determined by the regions S1, S2, S8, and S9, which are disposed within 20 micrometers from the outermost surfaces. The contribution of each of the region S4, S5, and S6, which are in middle positions in the thickness direction, is 2% or lower, which is marginal.

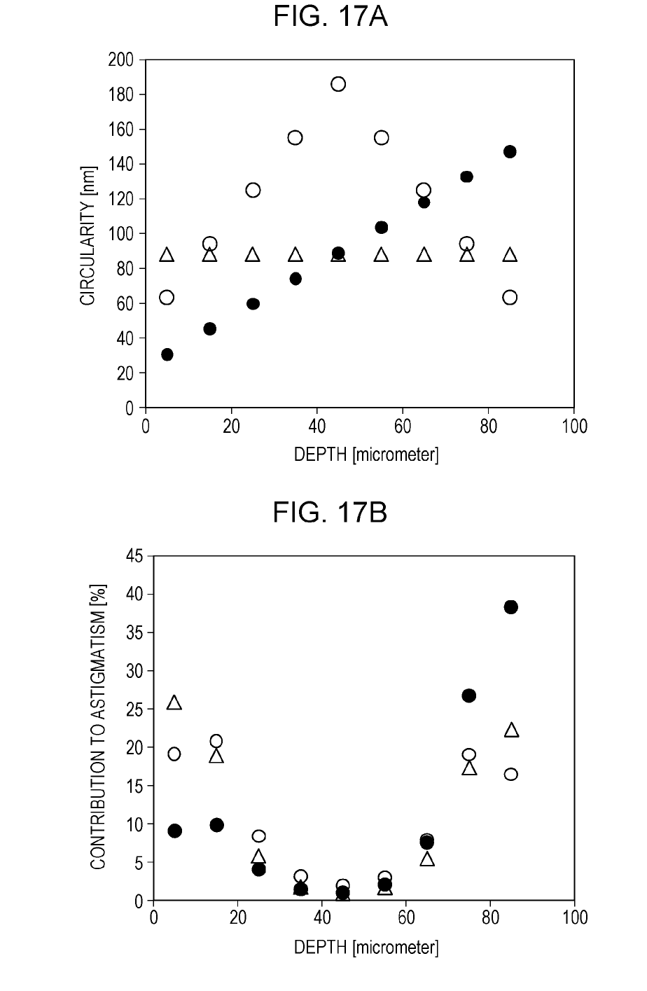

Next, the relationship between the magnitudes of aberration when the circularity actually has a distribution will be described. FIG. 17A illustrates distributions of the circularities of the regions S1 to S9. Open triangles represent a distribution when the regions S1 to S9 have the same circularity, open circles represent a distribution when the regions S1 and S9 have the smallest circularity and the circularity increases toward the region S5, and solid circles represent a distribution when the circularity increases from the region S1 toward the region S9.

In the case where silicon is deep dry etched from one direction as illustrated in FIG. 9, the circularity is likely to have the distribution represented by solid circles. In the case where silicon is deep dry etched from the front surface and the back surface, the circularity is likely to have the distribution represented by open circles. These two cases are important because these distributions typically occur in actual fabrication. FIG. 17B illustrates the contribution of astigmatism. The types of points in FIG. 17B correspond to those of FIG. 17A. In the case of solid circles, the contributions of the regions S1 and S2, which are near an outermost surface where the circularities, are low; and the contributions of the regions S8 and S9, which are near an opposite outermost surface, are high. As a result, about 84% of the aberration is determined by the regions S1, S2, S8, and S9, which are within 20 micrometers from the outermost surfaces. In the case of open circles, the contributions of middle regions S4, S5, and S6 are higher. However, the influence on the total aberration is small because the contributions of these regions are still low. As a result, about 76% of the aberration is determined by the regions S1, S2, S8, and S9, which are within 20 micrometers from the outermost surfaces.

As described above, in each of the cases of the distribution of the circularity, most of the aberration is determined by regions that are within 20 micrometers from the outermost surfaces, although the third region 7 has a total thickness of 100 micrometers. In particular, the contributions of the outermost surfaces are high. In the case of open circles in FIG. 17A, in which the circularity varies several fold within the thickness, the influence of the outermost surfaces is the largest. If the profile of the opening in a region in the thickness direction does not have an excessive variation in the shape or the surface condition, only the circularities at the front and back outermost surfaces may measured and the average value of the circularity may be used as the average circularity of the region. A representative circularity that is determined on the basis of such measurement can be used to examine the aberration with sufficiently good approximation. Therefore, if it is difficult to measure the distribution of circularity in the thickness direction, measurement method may be simplified in this way and thereby the shape of the opening cross section according to the present invention can be examined.

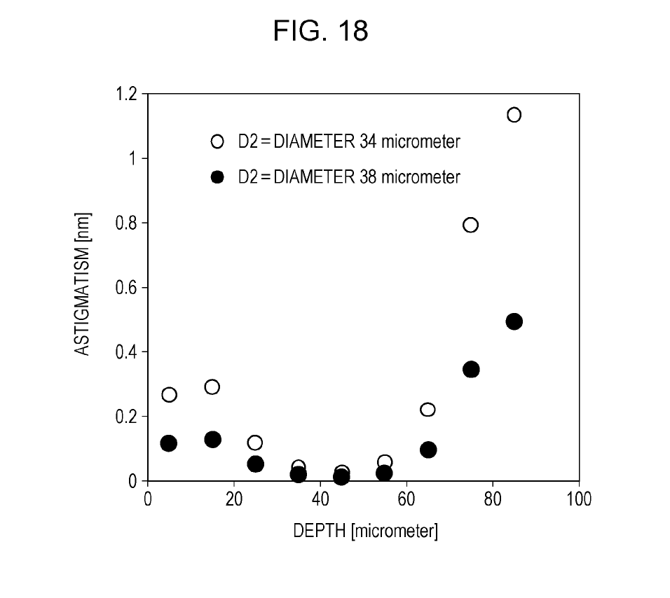

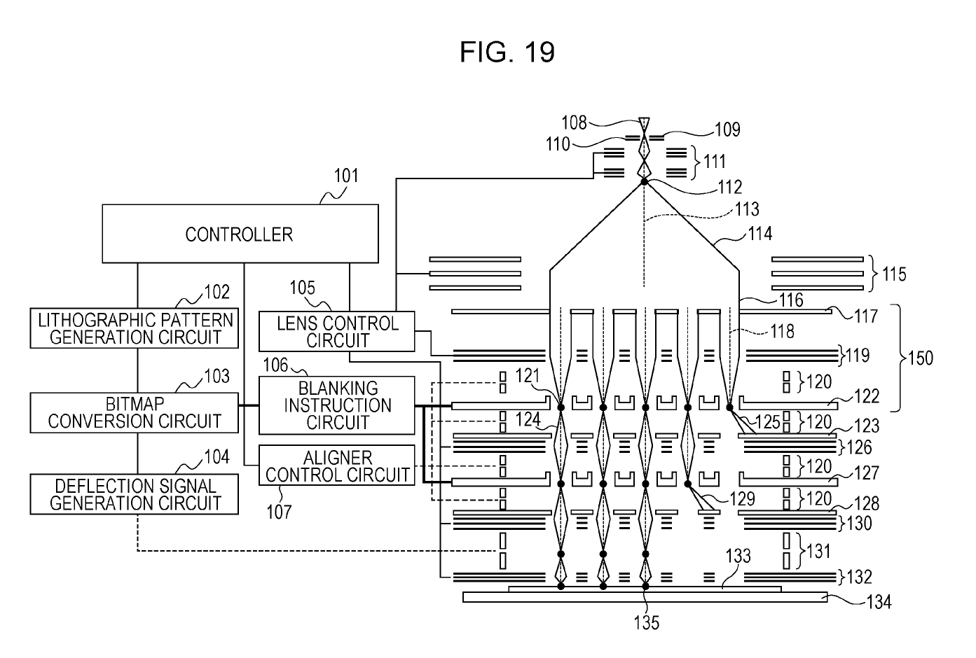

FIG. 18 shows the values of actual astigmatism obtained assuming that the circularity distribution is represented by solid circles in FIG. 17A for the cases where the diameter of the third region 7 is 34 micrometers and 38 micrometers. As described above, the larger the diameter, the smaller the aberration. In particular, differences in the astigmatism of the regions that are within 20 micrometers from the outermost surfaces are large. Thus, also regarding change in the diameters, the influence of the outermost surfaces is the largest. Therefore, as with the circularity, if the profile of the opening in a region in the thickness direction does not have excessive variations in shape or surface conditions, the average of the representative diameters at the front and back outermost surfaces may be used as the average representative diameter of the region.

Next, a method of manufacturing the present embodiment will be described. The first region, the second region, and the third region are bonded to each other through the first interface 13 and the second interface 14. Silicon on insulator (SOI) substrates each having a device layer with a thickness of 6 micrometers, which are to become the first region and the second region, an embedded oxide film layer, and a handle layer, are prepared. First, the openings 2A and 2B are formed in the device layers by performing high precision photolithography and dry etching of silicon. Subsequently, the entire substrate is thermally oxidized. The opening 2C is formed in a silicon substrate having a thickness of 88 micrometers, which is the same as that of the third region, by performing photolithography and deep dry etching of silicon. Then, the device layers of the SOI substrates, in which the opening 2A and 2B are formed, are directly bonded to the front and back surfaces of the silicon substrate in which the opening 2C is formed, through thermally oxidized films. Subsequently, by successively removing handle layers and embedded oxide film layers of the two SOI wafers and the thermally oxide films other than the bonding interfaces of the openings 2A and 2B, the electrodes 3A, 3B, and 3C each having the first region, the second region, and the third region can be formed. The present embodiment has the same effect not only in a bonded structure that is bonded through the interfaces 13 and 14 but also in a structure that has an interface at another position or that does not have an interface. However, in particular in the case where the regions are bonded through the interfaces 13 and 14, a step of forming the opening 2A and 2B, for which precision in the shape is required, and a step of forming the opening 2C can be independently performed.

Therefore, control of etching conditions can be precisely performed and the yield can be improved. In particular, the thicknesses of the openings 2A and 2B, for which near-perfect circularity is required, can be reduced, so that the openings can be formed with high precision. Moreover, the opening 2C can be formed with a process having a comparatively low precision, so that the manufacturing cost and the number of steps is reduced and the yield is improved. Furthermore, by using monocrystalline silicon, an electrode according to the present embodiment can be formed with high precision through the process of forming a high-precision opening such as photolithography or dry etching and wafer bonding through surfaces having high degree of flatness. Thus, as in this design example, an opening that having a diameter in the order of several tens of micrometers can be formed with a circularity in the order of nanometers.

When bonding is performed and the openings 2A and 2B and the opening 2C come into contact with each other at the interfaces 13 and 14, the edges of the openings are not located at the same position because the diameters that satisfy D1<D2 are different from each other. Therefore, when thermally oxidizing the openings 2A and 2C before bonding, although protrusions are formed at the edge portion because the thickness of the thermally oxidized film has a distribution, the bonding process is not hindered by these protrusions.

### Second Embodiment

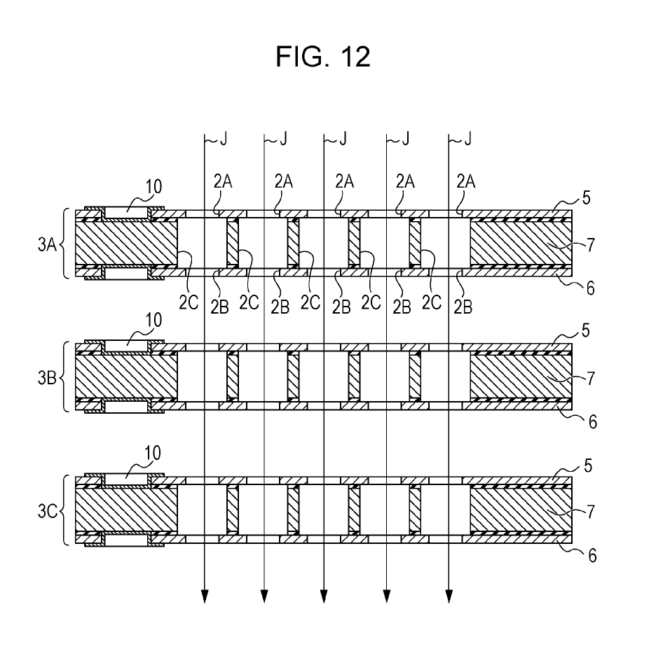

Referring to FIG. 12, a second embodiment of the present invention will be described. FIG. 11 is a sectional view of a charged particle beam lens. Portions having the same functions as those of the first embodiment will be denoted by the same numerals and description the effects the same as those of the first embodiment will be omitted. In the present embodiment and the first embodiment, each of the electrodes 3A, 3B, and 3C has a plurality of openings 2A, a plurality of openings 2B, and a plurality of openings 2C. In the present embodiment, as illustrated in FIG. 11, the charged particle beam lens is a lens array in which five openings are formed in each of the electrodes.

The diameter of the opening 2C is larger than that of the opening 2A. Because the diameter of the opening 2C is smaller than the pitch between adjacent openings, adjacent openings 2C are not connected with each other in the third region. Therefore, the lens array can be formed without reducing the rigidity of the entirety of the electrode.

Moreover, because the opening cross section can be formed with high precision, variation in the circularities of the opening cross sections of individual lenses of the lens array can be reduced. Because the circularity of an individual lens of the lens array has a random error, it is very difficult to correct the circularity individually. Therefore, by reducing the variation in the circularity of the opening cross sections can be reduced, a large-scale lens array can be formed.

In particular, when an electrode has a bonded structure, which can be manufactured with a method the same as that of the first embodiment, variation in the opening cross sections can be sufficiently reduced. If the alignment precision of bonding is low, displacement between the openings 2A and 2B occurs. However, this displacement can be easily corrected because the displacement is uniform in the entirety of the lens array. Therefore, this structure is appropriate for a large-scale lens array.

### Third Embodiment

FIG. 19 illustrates a multi-charged-particle-beam exposure apparatus using a charged particle beam lens according to the present invention. The present embodiment is a so-called multi-column type having projection systems individually.

A radiation electron beam that is emitted from an electron source 108 through an anode electrode 110 forms an irradiation optical system crossover 112 due to a crossover adjusting optical system 111.

As the electron source 108, a so-called thermionic electron source using LaB6 or BaO/W (dispenser cathode) is used.

The crossover adjusting optical system 111 includes electrostatic lenses with two tiers. Each of the electric lenses in the first and second tiers is a so-called einzel electrostatic lens that includes three electrodes in which a negative voltage is applied to a middle electrode and the upper and lower electrodes are grounded.

The electron beam, which is spreads with a wide angle from the irradiation optical system crossover 112 is collimated by a collimator lens 115 and an aperture array 117 is irradiated with the collimated beam. The aperture array 117 splits the electron beam into multi-electron beams 118. A focusing lens array 119 individually focuses the multi-electron beams 118 to a blanker array 122.

The focusing lens array 119 is an einzel electrostatic lens array including three electrodes having multiple openings and in which a negative voltage is applied the middle electrode and the upper and lower electrodes are grounded.

The aperture array 117 is disposed at the position of the pupil plane of the focusing lens array 119 (the position of the front focus of the focusing lens array 119) so that the aperture array 117 may serve to define the NA (half-angle of focus).

The blanker array 122, which is a device having an independent deflection electrode, performs ON/OFF control of individual beams in accordance with a lithographic pattern on the basis of a blanking signal generated by a lithographic pattern generation circuit 102, a bitmap conversion circuit 103, and a blanking instruction circuit 106.

In a beam-ON state, a voltage is not applied to a deflection electrode of the blanker array 122. In a beam-OFF state, a voltage is applied to a deflection electrode of the blanker array 122, so that the multi-electron beams are deflected. A multi-electron beam 125 that has been deflected by the blanker array 122 is blocked by a stop aperture array 123 disposed behind the blanker array 122, so that the beam is cut off.

In the present embodiment, the blanker array has a two-tier structure in which a second blanker array 127 and a second stop aperture array 128 respectively having structures the same as those of the blanker array 122 and the stop aperture array 123 are disposed in the second tier.

The multi-electron beams that have passed through the blanker array 122 are focused on the second blanker array 127 by a second focusing lens array 126. Then, the multi-electron beams are focused by third and fourth focusing lenses to a wafer 133. As with the focusing lens array 119, each of the second focusing lens array 126, a third focusing lens array 130, and a fourth focusing lens array 132 is an einzel electrostatic lens array.

In particular, the fourth focusing lens array 132 is an objective lens having a reduction ratio of 100. Thus, an electron beam 121 on the intermediate imaging plane of the blanker array 122 (having a spot diameter of 2 micrometers at FWHM) is reduced to 1/100 on a surface of the wafer 133 to form an image of the multi-electron beam having a spot diameter of about 20 nm at FWHM. The fourth focusing lens array 132 is the charged particle beam lens array according to the second embodiment of the present invention.

Scanning of the multi-electron beam on the wafer can be performed by using a deflector 131. The deflector 131 includes four-tier counter electrodes, so that two-stage deflection in the x and y directions can be performed (for simplicity, two-tier deflectors are illustrated as one unit). The deflector 131 is driven in accordance with a signal generated by the deflection signal generation circuit 104.

While a pattern is being formed, the wafer 133 is continuously moved in the X direction by a stage 134. An electron beam 135 on the wafer is deflected in the Y direction by the deflector 131 on the basis of a real-time measurement result obtained by a laser length measuring machine. On/off control of the beam is individually performed by the blanker array 122 and the second blanker array 127 in accordance with the lithographic pattern. Thus, a desired pattern can be formed on the wafer 133 with a high speed.

By using the charged particle beam lens array according to the present invention, focusing having only a small aberration is realized. Therefore, a multi-charged-particle-beam exposure apparatus that can form a fine pattern can be realized. Moreover, the electrode may have a large thickness even if the openings through which multi-beams pass are formed in a large area, so that the number of the multi-beams can be increased. Thus, a charged particles beam exposure apparatus that forms a pattern with a high speed can be realized.

The charged particle beam lens array according to the present invention can be used as any of the focusing lens array 119, the second focusing lens array 126, the third focusing lens array 130.

The charged particle beam lens according to the present invention can be used as a charged particle beam lithography apparatus using a single beam instated of using a plurality of beams as illustrated in FIG. 19. Also in this case, by using a lens having only a small aberration, a charged particles beam exposure apparatus that forms a fine pattern can be realized.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-056813, filed Mar. 15, 2011, which is hereby incorporated by reference herein in its entirety.

1. An electrostatic charged particle beam lens comprising:
an electrode including a flat plate having a first surface having a normal line extending in a direction of an optical axis and a second surface opposite to the first surface, the electrode having a through-hole extending from the first surface to the second surface,
wherein, when an opening cross section is defined as a cross section of the through-hole taken along a plane perpendicular to the normal line and a representative diameter is defined as a diameter of a circle obtained by performing regression analysis of the opening cross section, a representative diameter D1 of the opening cross section in a first region that is on the first surface side and a representative diameter of the opening cross section in a second region that is on the second surface side are each smaller than a representative diameter D2 of the opening cross section in a third region that is a region in the electrode disposed between the first surface and the second surface, and
wherein 0.4<D1/D2<1.0.

2. The charged particle beam lens according to claim 1 wherein, when an incircle and a circumcircle are respectively defined as two concentric circles having a smaller radius and a larger radius between which the opening cross section is disposed and having the smallest difference in the radii, a difference in the radii of the incircle and the circumcircle of the opening cross section in the first region and a difference in the radii of the incircle and the circumcircle of the opening cross section in the second region are each smaller than a difference in the radii of the incircle and the circumcircle of the opening cross section in the third region.

3. (canceled)

4. The charged particle beam lens according to claim 1, wherein a thickness of each of the first region and the second region is smaller than a thickness of the third region.

5. The charged particle beam lens according to claim 1, wherein a thickness of the first region is larger than ⅛ of the representative diameter in the first region and a thickness of the second region is larger than ⅛ of the representative diameter in the second region.

6. The charged particle beam lens according to claim 1, wherein at least one of the first region and the second region is stacked on or bonded to the third region.

7. The charged particle beam lens according to claim 1, wherein the electrode is covered by an electroconductive film.

8. The charged particle beam lens according to claim 1, wherein the electrode is an array having a plurality of openings and controlling electron optical characteristics of a plurality of charged particle beams.

9. An exposure apparatus comprising the charged particle beam lens according to claim 1 and using a charged particle beam.

10. The exposure apparatus according to claim 9 using a plurality of charged particle beams.
